(19) United States
(12) Patent Application Publication
(10) Pub. No.: US 2026/0005734 A1
(43) Pub. Date: Jan. 1, 2026

(54) ELECTRONIC DEVICE FOR PERFORMING IMPEDANCE MATCHING OF ANTENNA, AND OPERATION METHOD OF ELECTRONIC DEVICE

(71) Applicant: Samsung Electronics Co., Ltd., Suwon-si (KR)

(72) Inventors: Woosik CHO, Suwon-si (KR); Seungshik SHIN, Suwon-si (KR); Sukgi HONG, Suwon-si (KR)

(21) Appl. No.: 19/319,228

(22) Filed: Sep. 4, 2025

Related U.S. Application Data
(63) Continuation of application No. PCT/KR2024/002808, filed on Mar. 5, 2024.

(30) Foreign Application Priority Data
Mar. 9, 2023 (KR) 10-2023-0031009
Apr. 6, 2023 (KR) 10-2023-0045504

(51) Int. Cl. H04B 7/0413; H01Q 1/00; H01Q 1/24; H01Q 5/50; H03F 3/19

(52) U.S. Cl. CPC H04B 7/0413; H01Q 1/002; H01Q 1/246; H01Q 5/50; H03F 3/19

(57) ABSTRACT

An electronic device electronic device is provided. The electronic device includes a first antenna, a second antenna, memory, comprising one or more storage media, storing instructions, and at least one communication processor communicatively coupled to the first antenna, the second antenna, and the memory, wherein the instructions, when executed by the at least one communication processor individually or collectively, cause the electronic device to during an operation in a mode in which data is transmitted to a cellular network via the first antenna and the second antenna, identify a number of uplink layers allocated by the cellular network to the electronic device, in case that the number of uplink layers allocated to the electronic device during a specified time satisfies a specified condition, change an operation mode related to impedance matching of at least one of the first antenna and the second antenna from a first mode for improving performance of at least one antenna to a second mode for reducing consumption of an amplifier electrically connected to the at least one antenna, and perform the impedance matching of the at least one antenna in the second mode.

### CROSS-REFERENCE TO RELATED APPLICATION(S)

This application is a continuation application, claiming priority under 35 U.S.C. § 365 (c), of an International application No. PCT/KR2024/002808, filed on Mar. 5, 2024, which is based on and claims the benefit of a Korean patent application number 10-2023-0031009, filed on Mar. 9, 2023, in the Korean Intellectual Property Office, and of a Korean patent application number 10-2023-0045504, filed on Apr. 6, 2023, in the Korean Intellectual Property Office, the disclosure of each of which is incorporated by reference herein in its entirety.

### BACKGROUND

### 1. Field

The disclosure relates to an electronic device and an operation method of the electronic device. More particularly, the disclosure relates to technology that performs impedance matching of an antenna of an electronic device.

### 2. Description of Related Art

In order to meet the demand for wireless data traffic that has increased after the commercialization of 4^{th} generation (4G) communication systems, efforts to develop improved 5^{th} generation (5G) communication systems or pre-5G communication systems have been made. For this reason, the 5G communication system or the pre-5G communication system is called a beyond 4G network communication system or a post long-term evolution (LTE) system. In order to achieve a high data transmission rate, embodying the 5G communication system in a superhigh frequency (millimeter wave (mmWave)) band (e.g., 6 GHz or higher band), in addition to a band (6 GHz or less band) that LTE uses, is being considered. In association with the 5G communication system, there are ongoing discussions about beamforming, massive multiple-input and multiple-output (MIMO), full dimensional MIMO (FD-MIMO), array antenna, analog beamforming, and/or large scale antenna technologies.

The above information is presented as background information only to assist with an understanding of the disclosure. No determination has been made, and no assertion is made, as to whether any of the above might be applicable as prior art with regard to the disclosure.

### SUMMARY

An electronic device may support uplink multiple-input and multiple-output (UL-MIMO) that transmits data via a plurality of frequency band channels. When connected to a base station via a frequency band that supports UL-MIMO, the electronic device may achieve a high transmission speed by transmitting data to the base station via a plurality of channels.

In this instance, when the electronic device continuously performs data transmission based on UL-MIMO, the amount of power consumed may be increased and the temperature of the electronic device may be increased as compared with the case of transmitting data via a single channel. When the temperature of the electronic device is increased, the electronic device may stop performing UL-MIMO according to a thermal policy or may change to cellular communication that causes relatively low heat generation, and thus a data transmission speed of the electronic device may be decreased.

Aspects of the disclosure are to address at least the above-mentioned problems and/or disadvantages and to provide at least the advantages described below. Accordingly, an aspect of the disclosure is to provide an electronic device for performing impedance matching of an antenna, and an operation method of an electronic device.

Additional aspects will be set forth in part in the description which follows and, in part, will be apparent from the description, or may be learned by practice of the presented embodiments.

In accordance with an aspect of the disclosure, an electronic device is provided. The electronic device includes a first antenna, a second antenna, memory, comprising one or more storage media, storing instructions, and at least one communication processor communicatively coupled to the first antenna, the second antenna, and the memory, wherein the instructions, when executed by the at least one communication processor individually or collectively, cause the electronic device to during an operation in a mode in which data is transmitted to the cellular network via the first antenna and the second antenna, identify a number of uplink layers allocated by a cellular network to the electronic device in case that the number of uplink layers allocated to the electronic device during a specified time satisfies a specified condition, change an operation mode related to impedance matching of at least one of the first antenna and the second antenna from a first mode for improving performance of impedance matching of the at least one antenna to a second mode for reducing power consumption of an amplifier electrically connected to the at least one antenna, and perform impedance matching of the at least one antenna in the second mode.

In accordance with another aspect of the disclosure, a method of an electronic device is provided. The method includes during an operation in a mode in which data is transmitted to a cellular network via a first antenna and a second antenna, identifying a number of uplink layers allocated by a cellular network to the electronic device, in case that the number of uplink layers allocated to the electronic device during a specified time satisfies a specified condition, changing an operation mode related to impedance matching of at least one of the first antenna and the second antenna from a first mode for improving performance of at least one antenna to a second mode for reducing power consumption of an amplifier electrically connected to the at least one antenna, and performing impedance matching of the at least one antenna in the second mode.

In accordance with another aspect of the disclosure, one or more non-transitory computer-readable storage media storing one or more computer programs including computer-executable instructions that, when executed by one or more processors of an electronic device individually or collectively, cause the electronic device to perform operations are provided. The operations include during an operation in a mode in which data is transmitted to a cellular network via a first antenna and a second antenna, identifying a number of uplink layers allocated by the cellular network to the electronic device, in case that the number of uplink layers allocated to the electronic device during a specified time satisfies a specified condition, changing an operation mode related to impedance matching of at least one of the first antenna and the second antenna from a first mode for improving performance of at least one antenna to a second mode for reducing power consumption of an amplifier electrically connected to the at least one antenna, and performing impedance matching of the at least one antenna in the second mode.

An electronic device and an operation method of the electronic device according to an embodiment identifies the number of uplink layers allocated to the electronic device, and when the number of uplink layers satisfies a specified condition, changes an operation mode related to impedance matching of an antenna from a first mode that improves performance of the antenna to a second mode that reduces power consumption of an amplifier electrically connected to the antenna. Therefore, in the situation in which the number of uplink layers allocated to the electronic device is small, the electronic device reduces unnecessary power consumption and heat generation caused by operation of UL-MIMO, and increases a time of performing UL-MIMO and increase a data transmission speed.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram of an electronic device according to an embodiment of the disclosure;

FIG. 2 is a block diagram of an electronic device for supporting legacy network communication and 5G network communication according to an embodiment of the disclosure;

FIG. 3 is a diagram illustrating a protocol stack structure of a network 100 of legacy communication and/or 5G communication according to an embodiment of the disclosure;

FIGS. 4A, 4B, and 4C are diagrams illustrating wireless communication systems that provide networks of legacy communication and/or 5G communication according to various embodiments of the disclosure;

FIG. 4D is a diagram illustrating an electronic device and a base station according to an embodiment of the disclosure;

FIG. 5 is a block diagram of an electronic device according to an embodiment of the disclosure;

FIGS. 6A and 6B are diagrams illustrating an example of performing, by an electronic device according to an embodiment, impedance matching of a first antenna and/or a second antenna based on the number of uplink layers allocated to the electronic device according to various embodiments of the disclosure; and

FIG. 7 is a flowchart illustrating an operation method of an electronic device according to an embodiment of the disclosure.

Throughout the drawings, it should be noted that like reference numbers are used to depict the same or similar elements, features, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a wireless fidelity (Wi-Fi) chip, a Bluetooth® chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

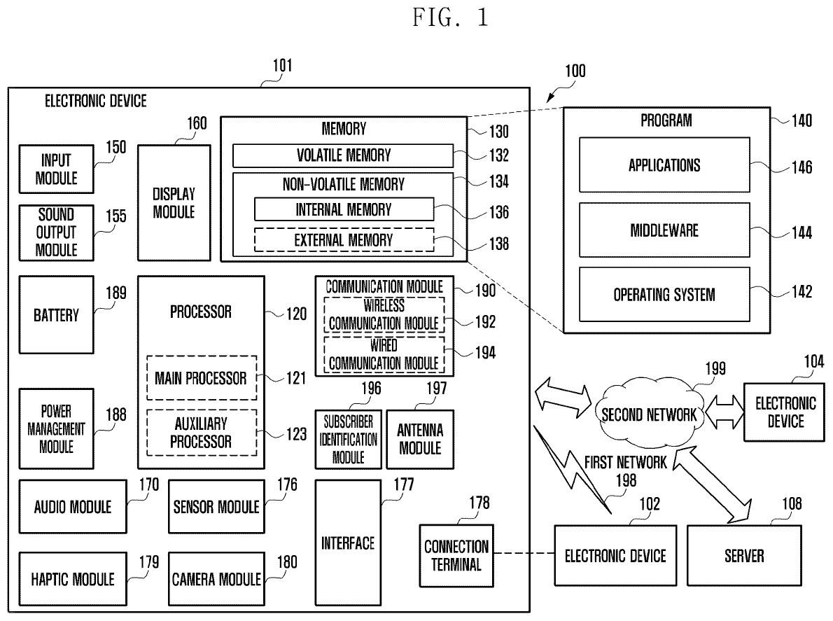

FIG. 1 is a block diagram illustrating an electronic device 101 in a network environment 100 according to an embodiment of the disclosure.

Referring to FIG. 1, the electronic device 101 in the network environment 100 may communicate with an electronic device 102 via a first network 198 (e.g., a short-range wireless communication network), or an electronic device 104 or a server 108 via a second network 199 (e.g., a long-range wireless communication network). According to an embodiment, the electronic device 101 may communicate with the electronic device 104 via the server 108. According to another embodiment, the electronic device 101 may include a processor 120, memory 130, an input device 150, a sound output device 155, a display device 160, an audio module 170, a sensor module 176, an interface 177, a haptic module 179, a camera module 180, a power management module 188, a battery 189, a communication module 190, a subscriber identification module (SIM) 196, or an antenna module 197. In some embodiments, at least one (e.g., the display device 160 or the camera module 180) of the components may be omitted from the electronic device 101, or one or more other components may be added in the electronic device 101. In some embodiments, some of the components may be implemented as single integrated circuitry. For example, the sensor module 176 (e.g., a fingerprint sensor, an iris sensor, or an illuminance sensor) may be implemented as embedded in the display device 160 (e.g., a display).

The processor 120 may execute, for example, software (e.g., a program 140) to control at least one other component (e.g., a hardware or software component) of the electronic device 101 coupled with the processor 120, and may perform various data processing or computation. In an embodiment, as at least part of the data processing or computation, the processor 120 may load a command or data received from another component (e.g., the sensor module 176 or the communication module 190) in volatile memory 132, process the command or the data stored in the volatile memory 132, and store resulting data in non-volatile memory 134. According to another embodiment, the processor 120 may include a main processor 121 (e.g., a central processing unit (CPU) or an application processor (AP)), and an auxiliary processor 123 (e.g., a graphics processing unit (GPU), an image signal processor (ISP), a sensor hub processor, or a communication processor (CP)) that is operable independently from, or in conjunction with, the main processor 121. Additionally or alternatively, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display device 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to another embodiment, the auxiliary processor 123 (e.g., an image signal processor or a communication processor) may be implemented as part of another component (e.g., the camera module 180 or the communication module 190) functionally related to the auxiliary processor 123.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input device 150 may receive a command or data to be used by other component (e.g., the processor 120) of the electronic device 101, from the outside (e.g., a user) of the electronic device 101. The input device 150 may include, for example, a microphone, a mouse, a keyboard, or a digital pen (e.g., a stylus pen).

The sound output device 155 may output sound signals to the outside of the electronic device 101. In an embodiment, the sound output device 155 may include, for example, a speaker or a receiver. The speaker may be used for general purposes, such as playing multimedia or playing record, and the receiver may be used for an incoming calls. According to an embodiment, the receiver may be implemented as separate from, or as part of the speaker.

The display device 160 may visually provide information to the outside (e.g., a user) of the electronic device 101. The display device 160 may include, for example, a display, a hologram device, or a projector and control circuitry to control a corresponding one of the display, hologram device, and projector. According to another embodiment, the display device 160 may include touch circuitry adapted to detect a touch, or sensor circuitry (e.g., a pressure sensor) adapted to measure the intensity of force incurred by the touch.

The audio module 170 may convert a sound into an electrical signal and vice versa. According to an embodiment, the audio module 170 may obtain the sound via the input device 150, or output the sound via the sound output device 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. In another embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). In another embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. The camera module 180 may include one or more lenses, image sensors, image signal processors, or flashes.

The power management module 188 may manage power supplied to the electronic device 101. According to one embodiment, the power management module 188 may be implemented as at least part of, for example, a power management integrated circuit (PMIC).

The battery 189 may supply power to at least one component of the electronic device 101. According to another embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. The communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may, for example, identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to another embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). The antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to some embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

Commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may, for example, provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

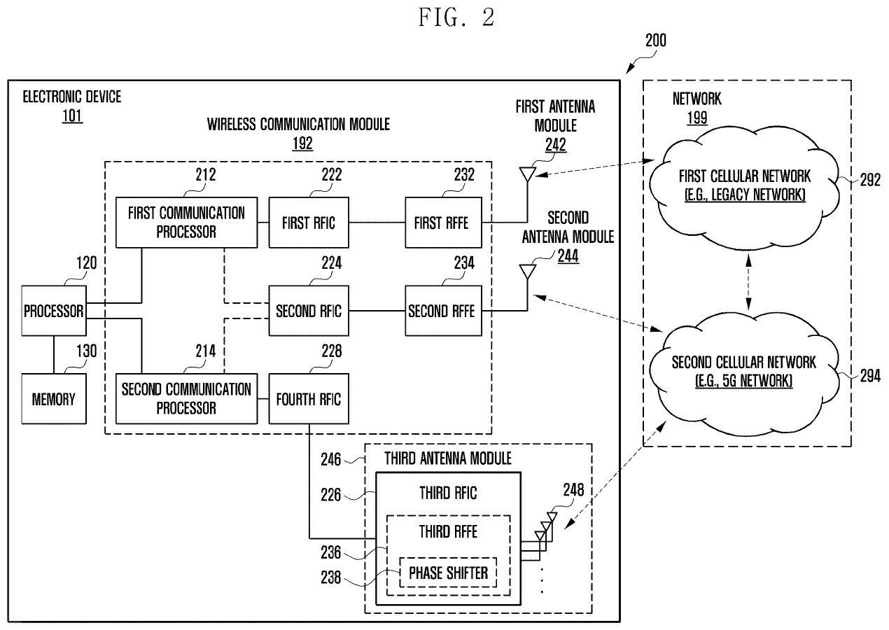

FIG. 2 is a block diagram 200 of an electronic device 101 for supporting legacy network communication and 5G network communication according to an embodiment of the disclosure.

Referring to FIG. 2, the electronic device 101 may include a first communication processor 212, a second communication processor 214, a first radio frequency integrated circuit (RFIC) 222, a second RFIC 224, a third RFIC 226, a fourth RFIC 228, a first radio frequency front end (RFFE) 232, a second RFFE 234, a first antenna module 242, a second antenna module 244, and an antenna 248. The electronic device 101 may further include the processor 120 and the memory 130. The network 199 may include a first network 292 and a second network 294. According to another embodiment, the electronic device 101 may further include at least one component among the components illustrated in FIG. 1, and the network 199 may further include at least one other network. The first communication processor 212, the second communication processor 214, the first RFIC 222, the second RFIC 224, the fourth RFIC 228, the first RFFE 232, and the second RFFE 234 may be included as at least a part of the wireless communication module 192. According to another embodiment, the fourth RFIC 228 may be omitted or may be included as a part of the third RFIC 226.

The first communication processor 212 may establish a communication channel of a band to be used for wireless communication with the first network 292, and may support legacy network communication via the established communication channel. According to certain embodiments, the first network may be a legacy network including 2G, 3G, 4G, or long term evolution (LTE) network. The second communication processor 214 may establish a communication channel corresponding to a designated band (e.g., approximately 6 GHz to 60 GHz) among bands to be used for wireless communication with the second network 294, and may support 5G network communication via the established channel. According to various embodiments, the second network 294 may be a 5G network defined in 3GPP. Additionally, according to an embodiment, the first communication processor 212 or the second communication processor 214 may establish a communication channel corresponding to another designated band (e.g., lower than 6 GHz) among bands to be used for wireless communication with the second network 294, and may support 5G network communication via the established channel. According to an embodiment, the first communication processor 212 and the second communication processor 214 may be implemented in a single chip or a single package. According to another embodiment, the first communication processor 212 or the second communication processor 214 may be implemented in a single chip or a single package, together with the processor 120, the sub-processor 123, or the communication module 190.

In the case of transmission, the first RFIC 222 may convert a baseband signal generated by the first communication processor 212 into a radio frequency (RF) signal in a range of approximately 700 MHz to 3 GHz used for the first network 292 (e.g., a legacy network). In the case of reception, an RF signal is obtained from the first network 292 (e.g., a legacy network) via an antenna (e.g., the first antenna module 242), and may be preprocessed via an RFFE (e.g., the first RFFE 232). The first RFIC 222 may, for example, convert the preprocessed RF signal to a baseband signal so that the base band signal is processed by the first communication processor 212.

In the case of transmission, the second RFIC 224 may convert a baseband signal generated by the first communication processor 212 or the second communication processor 214 into an RF signal (hereinafter, a 5G Sub6 RF signal) of a Sub6 band (e.g., lower than 6 GHz) used for the second network 294 (e.g., 5G network). In the case of reception, a 5G Sub6 RF signal is obtained from the second network 294 (e.g., a 5G network) via an antenna (e.g., the second antenna module 244), and may preprocessed by an RFFE (e.g., the second RFFE 234). The second RFIC 224 may, for example, convert the preprocessed 5G Sub6 RF signal into a baseband signal so that the baseband signal is processed by a corresponding communication processor from among the first communication processor 212 or the second communication processor 214.

The third RFIC 226 may convert a baseband signal generated by the second communication processor 214 into an RF signal (hereinafter, a 5G Above6 RF signal) of a 5G Above6 band (e.g., approximately 6 GHz to 60 GHz) to be used for the second network 294 (e.g., 5G network). In the case of reception, a 5G Above6 RF signal is obtained from the second network 294 (e.g., a 5G network) via an antenna (e.g., the antenna 248), and may be preprocessed by the third RFFE 236. The third RFIC 226 may convert the preprocessed 5G Above6 RF signal to a baseband signal so that the base band signal is processed by the second communication processor 214. According to an embodiment, the third RFFE 236 may be implemented as a part of the third RFIC 226.

According to another embodiment, the electronic device 101 may include the fourth RFIC 228, separately from or as a part of the third RFIC 226. In this instance, the fourth RFIC 228 may convert a baseband signal generated by the second communication processor 214 into an RF signal (hereinafter, an IF signal) in an intermediate frequency band (e.g., approximately 9 GHz to 11 GHZ), and may transfer the IF signal to the third RFIC 226. The third RFIC 226 may convert the IF signal to a 5G Above6 RF signal. In the case of reception, a 5G Above6 RF signal is received from the second network 294 (e.g., a 5G network) via an antenna (e.g., the antenna 248), and may be converted into an IF signal by the third RFFE 226. The fourth RFIC 228 may convert the IF signal to a baseband signal so that the base band signal is processed by the second communication processor 214.

The first RFIC 222 and the second RFIC 224 may be implemented as a single chip or at least a part of the single package. According to an embodiment, the first RFFE 232 and the second RFFE 234 may be implemented as a single chip or at least a part of the single package. According to an embodiment, at least one antenna module of the first antenna module 242 or the second antenna module 244 may be omitted, or may be combined with another antenna module so as to process RF signals in a plurality of bands.

In an embodiment, the third RFIC 226 and the antenna 248 may be disposed in the same substrate, and may form the third antenna module 246. For example, the wireless communication module 192 or the processor 120 may be disposed in a first substrate (e.g., main PCB). In this instance, the third RFIC 226 is disposed in a part (e.g., a lower part) of the second substrate (e.g., a sub PCB) separate from the first substrate and the antenna 248 is disposed on another part (e.g., an upper part), so that the third antenna module 246 is formed. By disposing the third RFIC 226 and the antenna 248 in the same substrate, the length of a transmission line therebetween may be reduced. For example, this may reduce a loss (e.g., attenuation) of a signal in a high-frequency band (e.g., approximate 6 GHz to 60 GHz) used for 5G network communication, the loss being caused by a transmission line. The electronic device 101 may improve the quality or speed of communication with the second network 294 (e.g., 5G network).

The antenna 248 may be implemented as an antenna array including a plurality of antenna elements which may be used for beamforming. In this instance, the third RFIC 226 may be, for example, a part of the third RFFE 236, and may include a plurality of phase shifters 238 corresponding to a plurality of antenna elements. In the case of transmission, each of the plurality of phase shifters 238 may shift the phase of a 5G Above6RF signal to be transmitted to the outside of the electronic device 101 (e.g., a base station of a 5G network) via a corresponding antenna element. In the case of reception, each of the plurality of phase shifters 238 may shift the phase of the 5G Above6 RF signal received from the outside via a corresponding antenna element into the same or substantially the same phase. This may, for example, enable transmission or reception via beamforming between the electronic device 101 and the outside.

The second network 294 (e.g., 5G network) may operate independently (e.g., Stand-Along (SA)) from the first network 292 (e.g., a legacy network), or may operate by being connected thereto (e.g., Non-Stand Alone (NSA)). For example, in the 5G network, only an access network (e.g., 5G radio access network (RAN) or next generation RAN (NG RAN)) may exist, and a core network (e.g., next generation core (NGC)) may not exist. In this instance, the electronic device 101 may access an access network of the 5G network, and may access an external network (e.g., the Internet) under the control of the core network (e.g., an evolved packed core (EPC)) of the legacy network. Protocol information (e.g., LTE protocol information) for communication with the legacy network or protocol information (e.g., New Radio (NR) protocol information) for communication with the 5G network may be stored in the memory 230, and may be accessed by another component (e.g., the processor 120, the first communication processor 212, or the second communication processor 214).

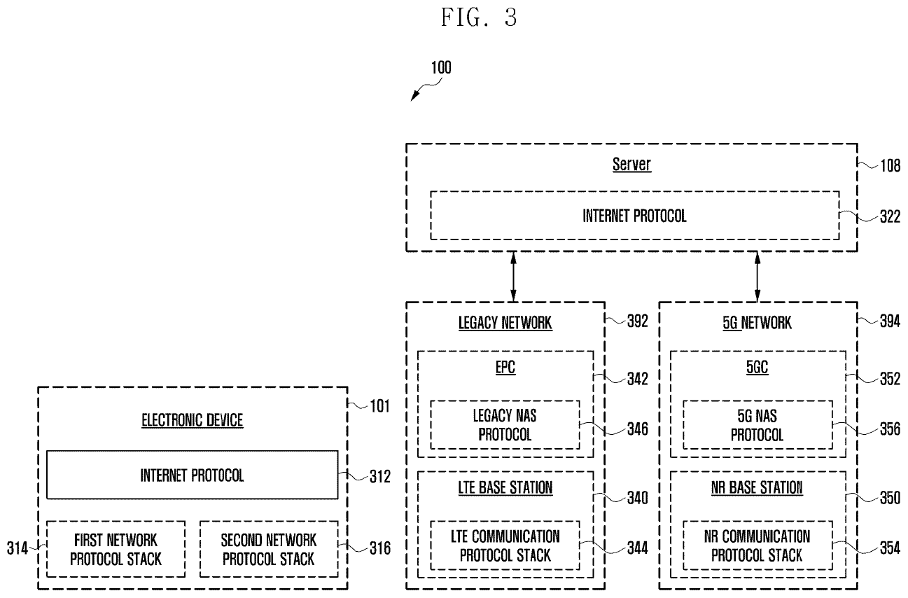

FIG. 3 illustrates a protocol stack structure of the network 100 of legacy communication and/or 5G communication according to an embodiment of the disclosure.

Referring to FIG. 3, the network 100 according to an illustrated embodiment may include the electronic device 101, a legacy network 392, a 5G network 394, and the server 108.

The electronic device 101 may include an Internet protocol 312, a first communication protocol stack 314, and a second communication protocol stack 316. The electronic device 101 may communicate with the server 108 through the legacy network 392 and/or the 5G network 394.

According to an embodiment, the electronic device 101 may perform Interne communication associated with the server 108 through the Internet protocol 312 (for example, a TCP, a UDP, or an IP). The Internet protocol 312 may be executed by, for example, a main processor (for example, the main processor 121 of FIG. 1) included in the electronic device 101.

According to another embodiment, the electronic device 101 may perform wireless communication with the legacy network 392 through the first communication protocol stack 314. According to another embodiment, the electronic device 101 may perform wireless communication with the 5G network 394 through the second communication protocol stack 316. The first communication protocol stack 314 and the second communication protocol stack 316 may be executed by, for example, one or more communication processors (for example, the wireless communication module 192 of FIG. 1) included in the electronic device 101.

The server 108 may include an Internet protocol 322. The server 108 may transmit and receive data related to the Internet protocol 322 to and from the electronic device 101 through the legacy network 392 and/or the 5G network 394. According to an embodiment, the server 108 may include a cloud computing server existing outside the legacy network 392 or the 5G network 394. According to another embodiment, the server 108 may include an edge computing server (or a mobile edge computing (MEC) server) located inside at least one of the legacy network or the 5G network 394.

The legacy network 392 may include an LTE eNode B (eNB) 340 and an EPC 342. The LTE eNB 340 may include an LTE communication protocol stack 344. The EPC 342 may include a legacy NAS protocol 346. The legacy network 392 may perform LTE wireless communication with the electronic device 101 through the LTE communication protocol stack 344 and the legacy NAS protocol 346.

The 5G network 394 may include an NR gNB 350 and a 5GC 352. The NR gNB 350 may include an NR communication protocol stack 354. The 5GC 352 may include a 5G NAS protocol 356. The 5G network 394 may perform NR wireless communication with the electronic device 101 through the NR communication protocol stack 354 and the 5G NAS protocol 356.

According to an embodiment, the first communication protocol stack 314, the second communication protocol stack 316, the LTE communication protocol stack 344, and the NR communication protocol stack 354 may include a control plane protocol for transmitting and receiving a control message and a user plane protocol for transmitting and receiving user data. The control message may include a message related to at least one of, for example, security control, bearer setup, authentication, registration, or mobility management. The user data may include, for example, the remaining data except other than the control message.

According to an embodiment, the control plane protocol and the user plane protocol may include a physical (PHY) layer, a medium access control (MAC) layer, a radio link control (RLC) layer, or a packet data convergence protocol (PDCP) layer. The PHY layer may channel-code and modulate data received from, for example, a higher layer (for example, the MAC layer), transmit the data through a radio channel, demodulate and decode the data received through the radio channel, and transmit the data to the higher layer. The PHY layer included in the second communication protocol stack 316 and the NR communication protocol stack 354 may further perform an operation related to beamforming. The MAC layer may logically/physically map, for example, data to a radio channel for transmitting and receiving the data and perform a hybrid automatic repeat request (HARQ) for error correction. The RLC layer may perform, for example, data concatenation, segmentation, or reassembly, and data sequence identification, reordering, or duplication detection. The PDCP layer may perform an operation related to, for example, ciphering of a control message and user data and data integrity. The second communication protocol stack 316 and the NR communication protocol stack 354 may further include a service data adaptation protocol (SDAP). The SDAP may manage allocation of radio bearers on the basis of quality of service (QOS) of user data.

According to certain embodiments, the control plane protocol may include a radio resource control (RRC) layer and a non-access stratum (NAS) layer. The RRC layer may process control, for example, data related to radio bearer setup, paging, or mobility management. The NAS may process, for example, a control message related to authentication, registration, or mobility management.

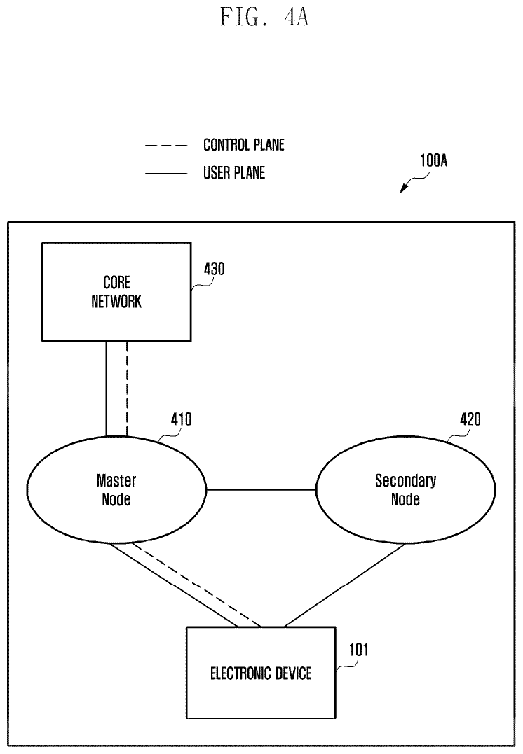

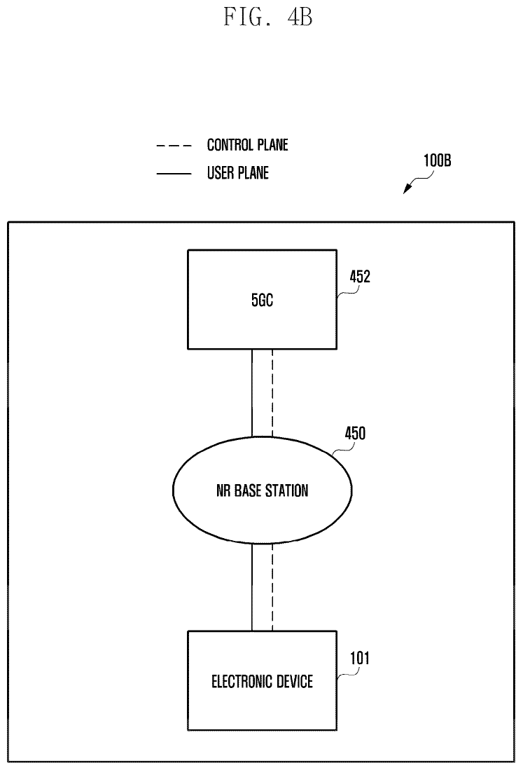

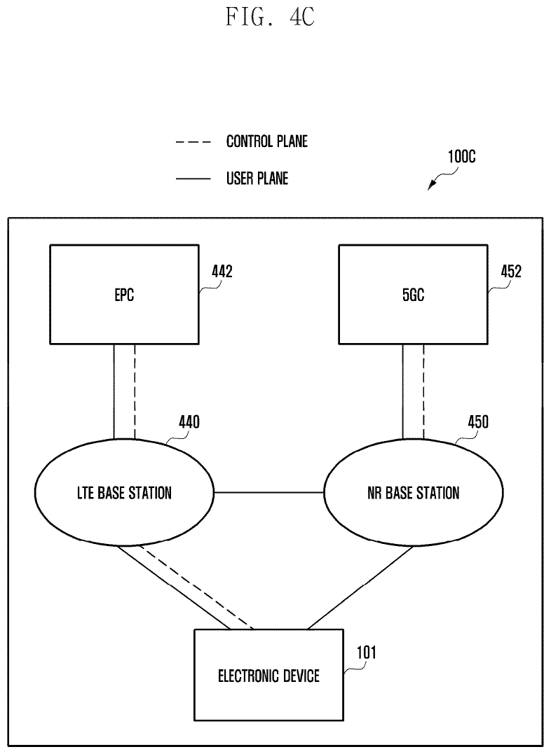

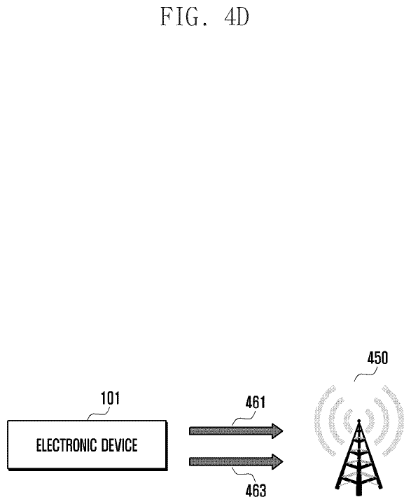

FIGS. 4A, 4B, and 4C illustrate a wireless communication system providing a network of legacy communication and/or 5G communication according to various embodiments of the disclosure.

Referring to FIGS. 4A, 4B, and 4C, network environments 100A, 100B, and 100C, respectively, may include at least one of a legacy network and a 5G network. The legacy network may include, for example, a 4G or LTE eNB 450 (for example, an eNodeB (eNB)) of the 3GPP standard supporting radio access with the electronic device 101 and an evolved packet core (EPC) 451 for managing 4G communication. The 5G network may include, for example, a new radio (NR) gNB 450 (for example, a gNodeB (gNB)) supporting radio access with the electronic device 101 and a 5^{th} generation core (5GC) 452 for managing 5G communication of the electronic device 101.

According to certain embodiments, the electronic device 101 may transmit and receive a control message and user data through legacy communication and/or 5G communication. The control message may include, for example, a control message related to at least one of security control of the electronic device 101, bearer setup, authentication, registration, or mobility management. The user data may be, for example, user data other than a control message transmitted and received between the electronic device 101 and a core network 430 (for example, the EPC 442).

Referring to FIG. 4A, the electronic device 101 according to an embodiment may transmit and receive at least one of a control message or user data to and from at least some of the 5G network (for example, the NR gNB 450 and the 5GC 452) using at least some of the legacy network (for example, the LTE eNB 440 and the EPC 442).

The network environment 100A may include a network environment for providing wireless communication dual connectivity (multi-radio access technology (RAT) dual connectivity (MR-DC)) to the LTE eNB 440 and the NR gNB 450 and transmitting and receiving a control message to and from the electronic device 101 through one core network 430 of the EPC 442 or the 5GC 452.

According to other embodiments, one of the MR-DC environment, the LTE eNB 440 or the NR gNB 450 may operate as a master node (MN) 410, and the other may operate as a secondary node (SN) 420. The MN 410 may be connected to the core network 430 and transmit and receive a control message. The MN 410 and the SN 420 may be connected to each other through a network interface and transmit and receive a message related to radio resource (for example, communication channel) management.

According to certain embodiments, the MN 410 may include the LTE eNB 450, the SN 420 may include the NR gNB 450, and the core network 430 may include the EPC 442. For example, a control message may be transmitted and received through the LTE eNB 440 and the EPC 442, and user data may be transmitted and received through the LTE eNB 450 and the NR gNB 450.

Referring to FIG. 4B, according to certain embodiments, the 5G network may independently transmit and receive a control message and user data to and from the electronic device 101.

Referring to FIG. 4C, the legacy network and the 5G network according to certain embodiments may independently provide data transmission and reception. In an example, the electronic device 101 and the EPC 442 may transmit and receive a control message and user data through the LTE eNB 450. According to another embodiment, the electronic device 101 and the 5GC 452 may transmit and receive a control message and user data through the NR gNB 450.

According to certain embodiments, the electronic device 101 may be registered in at least one of the EPC 442 or the 5GC 450 and transmit and receive a control message.

According to other embodiments, the EPC 442 or the 5GC 452 may interwork and manage communication of the electronic device 101. For example, movement information of the electronic device 101 may be transmitted and received through an interface between the EPC 442 and the 5GC 452.

FIG. 4D is a diagram illustrating an electronic device and a base station according to an embodiment of the disclosure.

Referring to FIG. 4D, an electronic device (e.g., electronic device 101 of FIG. 1) may be connected to a cellular network (e.g., 5G network 394 of FIG. 3) via a base station (e.g., NR base station 450 of FIG. 4C), and may perform cellular communication.

The base station 450 may be a base station that supports first cellular communication. The first cellular communication is any one of the various cellular communication schemes that the electronic device 101 is capable of supporting, and may be, for example, a communication scheme performed on the second cellular network 294 of FIG. 2. For example, the first cellular communication may be a communication scheme that uses a 5G mobile communication scheme (e.g., new radio). In an embodiment, the base station 450 may be a base station that supports a standalone mode supported by the first cellular communication. The standalone mode may be a mode in which the electronic device 101 transmits or receives data using a base station that supports the first cellular communication. The electronic device 101 may be connected to the base station 450, and may transmit or receive data.

The electronic device 101 and the base station 450 may support uplink multiple-input and multiple-output (UL-MIMO), which is a mode that transmits data via a plurality of frequency band channels. When connected to the base station 450 via a frequency band that supports UL-MIMO, the electronic device 101 may transmit data to the base station 450 via a plurality of channels 461 and 463.

Although, for ease of description, it is described that the electronic device 101 and the base station 450 support UL-MIMO, the disclosure may be applied to various communication schemes (e.g., carrier aggregation or new radio-dual connectivity (NR-DC)) that transmit data via a plurality of frequency band channels, in addition to UL-MIMO.

The situation in which the electronic device 101 transmits data to the base station 450 via the plurality of channels 461 and 463 may cause an increase of power consumption as compared with the situation in which the electronic device 101 transmits data to the base station 450 via a single channel. The increase in the power consumption may lead an increase of the temperature of the electronic device 101.

The electronic device 101 may perform various operations in order to decrease the temperature of the electronic device 101.

According to an embodiment, in order to decrease the temperature of the electronic device 101, the electronic device 101 may transmit data to the base station 450 via a single channel, instead of UL-MIMO, and the data transmission via the single channel may cause deterioration in a data transmission speed.

According to another embodiment, the electronic device 101 may disconnect from the first cellular communication and may connect to the second cellular communication in order to decrease the temperature of the electronic device 101. The second cellular communication is any one of the various cellular communication schemes that an electronic device (e.g., electronic device 101 of FIG. 1) is capable of supporting, and may be, for example, a communication scheme performed on the first cellular network 292 of FIG. 2. For example, the second cellular communication may be a communication scheme that uses a 4G mobile communication scheme (e.g., long term evolution).

The second cellular communication may be cellular communication that performs data communication using a relatively lower frequency band than that of the first cellular communication, and a data transmission speed based on the second cellular communication may be lower than a data transmission speed based on the first cellular communication. Therefore, the connection to the second cellular communication may cause deterioration in a data transmission speed.

In the state in which the electronic device 101 is capable of supporting UL-MIMO, the electronic device 101 may be assigned with a single layer, as opposed to a plurality of layers, from the cellular network 394. When the electronic device 101 is assigned with a single layer, a relatively low transmission speed may be achieved as compared with the case in which a plurality of layers are allocated, and thus the performance of communication performed by the electronic device 101 may be lowered.

Hereinafter, an embodiment in which the electronic device 101 reduces power consumption and/or heat generation based on the number of allocated layers will be described.

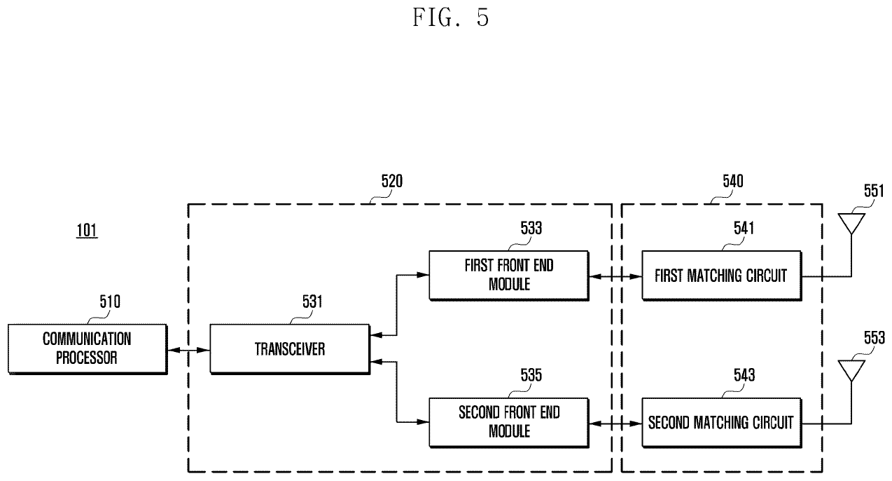

FIG. 5 is a block diagram of an electronic device according to an embodiment of the disclosure.

Referring to FIG. 5, an electronic device 500 (e.g., electronic device 101 of FIG. 1) according to an embodiment may include a communication processor 510, a wireless communication circuit 520, a first matching circuit 541, a second matching circuit 543, a first antenna 551, and/or a second antenna 553.

According to an embodiment, the communication processor 510 may perform various operations for wireless communication on a cellular network. For example, the communication processor 510 may establish a communication channel of a band to be used for wireless communication with the cellular network, and may support wireless communication via the established communication channel.

Under the control of the communication processor 510, the wireless communication circuit 520 may receive a signal, emitted from the outside, via the first antenna 551 or the second antenna 553, or may emit a signal, transmitted from the communication processor 510, via the first antenna 551 or the second antenna 553. The wireless communication circuit 520 may include a transceiver 531, a first front end module 533, and/or a second front end module 535.

According to another embodiment, the transceiver 531 may perform various operations that process a signal received from the communication processor 510. For example, the transceiver 531 may perform a modulation operation on a signal received from the communication processor 521. For example, the transceiver 531 may perform a frequency modulation operation that converts a baseband signal to a radio frequency (RF) signal used for cellular communication. The transceiver 531 may perform a demodulation operation on a signal received from the outside via the first antenna 551 or second antenna 553. For example, the transceiver 531 may perform a frequency demodulation operation that converts a radio frequency (RF) signal to a baseband signal.

Although the one transceiver 531 is illustrated in FIG. 5, the electronic device 101 may include a plurality of transceivers. For example, when the electronic device 101 includes a plurality of transceivers, the first front end module 533 and/or the second front end module 535 may be connected to different transceivers.

The first front end module 533 may include various components, including an amplifier (not illustrated) that amplifies a signal transmitted from the transceiver 531 and transmits the same to the first antenna 551, a low-noise amplifier (LNA) (not illustrated) that amplifies a signal received via the first antenna 551 and transmits the same to the transceiver 531, or a filter.

According to an embodiment, the wireless communication circuit 520 may support a communication scheme using at least two frequency bands. According to an embodiment, the wireless communication circuit 520 may support uplink multiple-input and multiple-output (UL-MIMO) that is a data transmission scheme using a plurality of frequency bands. To support UL-MIMO, the wireless communication circuit 520 may include the first front end module 533 that outputs a signal of a first frequency band via the first antenna 551 or receives a signal of the first frequency band via the first antenna 551, and/or the second front end module 535 that outputs a signal of a second frequency band (e.g., 5G cellular communication frequency band of 2500 MHz˜ 2690 Mhz (N7)) via the second antenna 553 or receives a signal of the second frequency band via the second antenna 553.

A matching circuit 540 may be disposed between the wireless communication circuit 520 and an antenna, and may perform impedance matching of the first antenna 551 and/or second antenna 553. The matching circuit 540 may include various components (e.g., a capacitor, a passive element embodied as an inductor, or an active element embodied as a transistor) in order to perform impedance matching of the first antenna 551 and/or second antenna 553 (e.g., matching input impedance or output impedance of the first antenna 551 to 5052). According to an embodiment, based on a control signal transmitted from the communication processor 510, the matching circuit 540 may perform impedance matching of the first antenna 551 and/or second antenna 553.

According to another embodiment, the matching circuit 540 may be embodied as the single matching circuit 540 and may be electrically connected to the first antenna 551 and/or the second antenna 553. For example, a ground terminal of the first antenna 551 and/or second antenna 553 may be connected to a ground terminal of the matching circuit 540.

According to another example, the matching circuit 540 may include the first matching circuit 541 and/or the second matching circuit 543. The first matching circuit 541 may be disposed between the wireless communication circuit 520 and the first antenna 551, and may perform impedance matching of the first antenna 551. The first matching circuit 541 may include various components (e.g., a capacitor, a passive element embodied as an inductor, or an active element embodied as a transistor) in order to perform impedance matching of the first antenna 551 (e.g., matching input impedance or output impedance of the first antenna 551 to 5052). For example, based on a control signal transmitted from the communication processor 510, the first matching circuit 541 may perform impedance matching of the first antenna 551.

According to yet another embodiment, the communication processor 510 may perform impedance matching of the first antenna 551 in one of the various operation modes related to impedance matching of the first antenna 551. For example, the various operation modes related to impedance matching of the first antenna 551 may include a first mode that improves performance of impedance matching of the first antenna 551 and a second mode that reduces power consumption of an amplifier (e.g., amplifier included in the first front end module 533) electrically connected to the first antenna 551. For example, the communication processor 510 may perform impedance matching of the first antenna 551 by inputting an antenna code corresponding to a configured operation mode to the first matching circuit 541. For example, the antenna code may refer to control data for controlling the various components included in the first matching circuit 541.

In an embodiment, the second matching circuit 543 may be disposed between the wireless communication circuit 520 and the second antenna 553, and may perform impedance matching of the second antenna 553. The second matching circuit 543 may include various components (e.g., a capacitor, a passive element embodied as an inductor, or an active element embodied as a transistor) in order to perform impedance matching of the second antenna 553 (e.g., matching input impedance or output impedance of the second antenna 553 to 5052). For example, based on a control signal transmitted from the communication processor 510, the second matching circuit 543 may perform impedance matching of the second antenna 553.

The communication processor 510 may perform impedance matching of the second antenna 553 in one of the various operation modes related to impedance matching of the second antenna 553. For example, the various operation modes related to impedance matching of the second antenna 553 may include a first mode that improves performance of impedance matching of the second antenna 553 and a second mode that reduces power consumption of an amplifier (e.g., amplifier included in the second front end module 535) electrically connected to the second antenna 553. For example, the communication processor 510 may perform impedance matching of the second antenna 553 by inputting an antenna code corresponding to a configured operation mode to the second matching circuit 543. For example, the antenna code may refer to control data for controlling the various components included in the second matching circuit 543.

In another embodiment, the communication processor 510 may support UL-MIMO. UL-MIMO may be a communication scheme of performing cellular communication with a base station (e.g., base station 450 of FIG. 4D) via at least two channels. According to an embodiment, when connected to the base station 450 via channels that support UL-MIMO, the communication processor 510 may transmit data to the base station 450 via the first antenna 551 and the second antenna 553. In the case in which UL-MIMO is supported, the first antenna 551 may be used for data transmission via one channel, and the second antenna 553 may be used for data transmission via another channel.

Hereinafter, an embodiment that performs impedance matching of the first antenna 551 and/or second antenna 553 so that the electronic device 101 performs UL-MIMO as long as possible with low heat generation and/or power consumption, will be described.

The communication processor 510 may identify the number of uplink layers allocated by the cellular network 394 to the electronic device 101 during operation in a mode (UL-MIMO) that transmits data to the cellular network 394 via the first antenna 551 and the second antenna 553.

According to an embodiment, when a size of data transmitted to the cellular network 394 satisfies a specified condition, the communication processor 510 may identify the number of uplink layers allocated to the electronic device 101. For example, the specified condition may be a condition related to a situation expected to have high heat generation and/or high power consumption. According to an embodiment, the specified condition may include a condition that a size (or throughput) of data transmitted or received during a specified time is greater than or equal to (or exceeds) a specified size (e.g., an average of approximately 17.5 Mbps over 10 seconds).

The communication processor 510 may identify the number of uplink layers allocated to the electronic device 101 upon detecting that a predetermined component of the electronic device 101 is activated. For example, the predetermined component may be a component that causes high heat generation and/or high power consumption. According to an embodiment, the predetermined component may include a display, a front camera, or a rear camera of the electronic device 101.

The communication processor 510 may, for example, identify the number of uplink layers allocated to the electronic device 101 based on control information received from the cellular network 394 via the base station 450.

According to an embodiment, the communication processor 510 may receive downlink control information (DCI) 1_0 from the cellular network 394. The communication processor 510 may identify the number of uplink layers allocated to the electronic device 101 by identifying a field (e.g., precoding information and number of layers) included in the DCI 1_0.

According to an embodiment, the communication processor 510 may receive the DCI 1_0 from the cellular network 394. The communication processor 510 may identify (or estimate) the number of uplink layers based on the number of SRSs included in a sounding reference signal (SRS) resource indicator among the fields included in the DCI 1_0.

During operation in UL-MIMO, the communication processor 510 may continuously identify the number of uplink layers allocated to the electronic device 101, and may identify whether the number of uplink layers satisfies a specified condition. For example, the communication processor 510 may identify whether the average of the number of uplink layers allocated to the electronic device 101 satisfies a specified condition. For example, the specified condition may be a condition in which the electronic device 101 has difficulty in achieving high throughput while operating in UL-MIMO. For example, to achieve high throughput while the electronic device 101 operates in UL-MIMO, the electronic device 101 may need to be assigned with a higher number of uplink layers from the cellular network 394. Therefore, the specified condition may be a condition that the number of uplink layers allocated to the electronic device 101 is less than or equal to (or less than) a specified value. According to an embodiment, the specified condition may include a condition that the number of uplink layers or the average of the number of uplink layers is less than or equal to (or less than) a specified value (e.g., approximately 1.5).

According to an embodiment, when the number of uplink layers does not satisfy a specified condition, the communication processor 510 may configure (or maintain) an operation mode related to impedance matching of at least one of the first antenna 551 and the second antenna 553 as the first mode that improves the performance of the antenna.

According to another embodiment, when the number of uplink layers satisfies a specified condition, the communication processor 510 may change an operation mode related to impedance matching of at least one of the first antenna 551 and the second antenna 553 from the first mode that improves the performance of the antenna to the second mode that reduces power consumption of an amplifier electrically connected to the at least one antenna. For example, the first mode may be a mode that performs impedance matching when a voltage with a higher magnitude is applied to the amplifier, the magnitude of the voltage being higher than a magnitude of a voltage (or current) applied to the amplifier electrically connected to the antenna when the matching circuit 540 operates in the second mode. According to another embodiment, to operate in the first mode, the communication processor 510 may control at least one of the first matching circuit 541 or the second matching circuit 543 by using an antenna code (e.g., performance best code) corresponding to the first mode. For example, the second mode may be a mode that performs impedance matching when a voltage with a lower magnitude is applied to the amplifier, the magnitude of the voltage being lower than a magnitude of a voltage (or current) applied to the amplifier electrically connected to the antenna when the matching circuit operates in the first mode. To operate in the second mode, the communication processor 510 may control at least one of the first matching circuit 541 or the second matching circuit 543 by using an antenna code (e.g., current saving code) corresponding to the second mode.

In an embodiment, the communication processor 510, in the configured operation mode (e.g., second mode), may decrease a voltage (or bias voltage) applied to an amplifier included in a front end module (e.g., first front end module 533) electrically connected to at least one antenna (e.g., first antenna 551), and the communication processor 510 may input an antenna code corresponding to the configured operation mode to a matching circuit electrically connected to the at least one antenna, thereby performing impedance matching of the at least one antenna. For example, the antenna code may refer to control data for controlling various components included in the matching circuit. The communication processor 510 may configure the matching circuit corresponding to the antenna to the second mode that may reduce power consumption, and may perform impedance matching of the antenna, and thus may minimize power consumption and heat generation caused by operation of UL-MIMO, and may prevent UL-MIMO disablement caused due to an increase in the temperature of the electronic device 101. Accordingly, the electronic device 101 may perform UL-MIMO for a relatively long time.

The communication processor 510 may select an antenna (e.g., first antenna 551) that shows higher performance between the first antenna 551 and the second antenna 553, as an antenna for which an operation mode related to impedance matching is to be changed. For example, when an operation mode related to impedance matching of an antenna having relatively higher performance is configured to an operation mode that may consume a relatively low amount of power, deterioration in a data transmission speed may be minimized and power consumption may be reduced.

According to an embodiment, the communication processor 510 may use the quality of signals (e.g., reference signals received power (RSRP)) that may be received via the first antenna 551 and the second antenna 553, when determining the performance of the first antenna 551 and the second antenna 553. According to another embodiment, the communication processor 510 may compare an RSRP of a signal received via the first antenna 551 and an RSRP received via the second antenna 553, and may select an antenna (e.g., first antenna 551) corresponding to a higher RSRP. The communication processor 510 may perform impedance matching of the first antenna 551 by inputting an antenna code corresponding to the configured operation mode to the first matching circuit 541.

According to an embodiment, the communication processor 510 may use maximum output strengths (maximum transmit power (MTP)) of the first antenna 551 and the second antenna 553, when determining the performance of the first antenna 551 and the second antenna 553. According to an embodiment, the communication processor 510 may compare a strength (MTP) of a signal capable of being output via the first antenna 551 and a strength (MTP) of a signal capable of being output via the second antenna 553, and may select an antenna (e.g., first antenna 551) capable of performing output with a higher strength. The communication processor 510 may perform impedance matching of the first antenna 551 by inputting an antenna code corresponding to the configured operation mode to the first matching circuit 541.

The communication processor 510 may change an operation mode related to impedance matching of at least one antenna to the second mode, and may perform impedance matching of the at least one antenna in the second mode.

According to an embodiment, the communication processor 510 may perform impedance matching of at least one antenna in the second mode, and may identify (or monitor) a temperature of a portion of the electronic device 101.

According to an embodiment, when a temperature of a portion of the electronic device 101 is decreased by a specified magnitude or greater (or greater than the specified magnitude), the communication processor 510 may change an operation mode related to impedance matching of at least one antenna again from the second mode to the first mode.

The communication processor 510, in the first mode, may increase a voltage (or bias voltage) applied to an amplifier included in a front end module (e.g., first front end module 533) electrically connected to at least one antenna (e.g., first antenna 551), and the communication processor 510 may input an antenna code corresponding to the first mode to a matching circuit electrically connected to the at least one antenna, thereby performing impedance matching of the at least one antenna. For example, the antenna code may refer to control data for controlling the various components included in the matching circuit. The communication processor 510 may perform impedance matching of the at least one antenna by inputting the antenna code corresponding to the configured operation mode to the matching circuit corresponding to the at least one antenna. According to an embodiment, when the temperature is decreased again, the communication processor 510 may change to the first mode that may achieve higher throughput than the second mode, so as to improve a data transmission speed.

According to another embodiment, while a matching circuit corresponding to an antenna (e.g., first antenna 551) operates in the second mode, when a temperature of a portion of the electronic device 101 is increased by a specified magnitude or greater (or greater than the specified magnitude), the communication processor 510 may change (or configure), to the second mode, an operation mode related to impedance matching of another antenna (e.g., second antenna 553) corresponding to a matching circuit operating in the first mode.

According to an embodiment, the communication processor 510, in the configured operation mode (e.g., second mode), may decrease a voltage (or bias voltage) applied to an amplifier included in a front end module (e.g., second front end module 535) electrically connected to the other antenna (e.g., second antenna 553), and the communication processor 510 may input an antenna code corresponding to the configured operation mode to the matching circuit (e.g., second matching circuit 543) electrically connected to the other antenna (e.g., second antenna 553), thereby performing impedance matching of the other antenna. In an example, the antenna code may refer to control data for controlling the various components included in the matching circuit. By performing impedance matching of the other antenna in the second mode that may reduce power consumption, the communication processor 510 may reduce power consumption and heat generation caused by operation of UL-MIMO, and may prevent UL-MIMO disablement that may be caused due to an increase in the temperature of the electronic device 101. Accordingly, the electronic device 101 may perform UL-MIMO for a relatively long time.

According to an embodiment, the communication processor of the wireless communication circuit 520 may configure an operation mode for impedance matching of the first antenna 551 and the second antenna 553 to the second mode, and may identify (or monitor) a temperature of a portion of the electronic device 101.

According to an embodiment, when a temperature of a portion of the electronic device 101 is increased by a specified magnitude or greater (or greater than the specified magnitude), the communication processor of the wireless communication circuit 520 may disable UL-MIMO and may transmit data to the base station 450 via a single channel. For example, when a temperature of a portion of the electronic device 101 is increased by a specified magnitude or greater (or greater than the specified magnitude), the communication processor of the wireless communication circuit 520 may disconnect from the first cellular communication and may transmit data to the cellular network 394 via second cellular communication.

According to an embodiment, when a temperature of a portion of the electronic device 101 is decreased by a specified magnitude or greater (or greater than the specified magnitude), the communication processor of the wireless communication circuit 520 may change an operation mode related to impedance matching of at least one antenna again from the second mode to the first mode.

According to an embodiment, the communication processor of the wireless communication circuit 520 may select an antenna that shows lower performance between the first antenna 551 and the second antenna 553, and may change an operation mode related to impedance matching of the selected antenna from the second mode to the first mode.

According to an embodiment, the communication processor 510 may use the quality of signals (e.g., reference signals received power (RSRP)) that may be received via the first antenna 551 and the second antenna 553, when determining the performance of the first antenna 551 and the second antenna 553. According to an embodiment, the communication processor 510 may compare an RSRP of a signal received via the first antenna 551 and an RSRP received via the second antenna 553, and may select an antenna (e.g., second antenna 553) corresponding to a lower RSRP. The communication processor 510 may perform impedance matching of the second antenna 553 by inputting, to the second matching circuit 543, an antenna code corresponding to the second mode that is a configured operation mode.

According to an embodiment, the communication processor 510 may use maximum output strengths (maximum transmit power (MTP)) of the first antenna 551 and the second antenna 553, when determining the performance of the first antenna 551 and the second antenna 553. The communication processor 510 may compare a strength (MTP) of a signal capable of being output via the first antenna 551 and a strength (MTP) of a signal capable of being output via the second antenna 553, and may select an antenna (e.g., second antenna 553) capable of performing output with a lower strength. The communication processor 510 may perform impedance matching of the second antenna 553 by inputting, to the second matching circuit 543, an antenna code corresponding to the second mode that is a configured operation mode.

Although the above description provides an example in which the electronic device 101 operates in UL-MIMO, the above description may be applicable to various communication schemes (e.g., carrier aggregation or new radio-dual connectivity (NR-DC)) that transmit data simultaneously via the first antenna 515 and the second antenna 553.

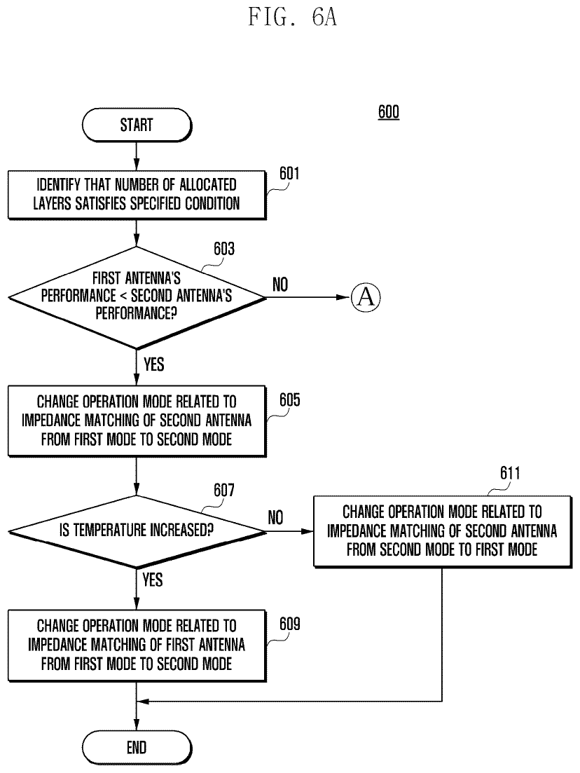

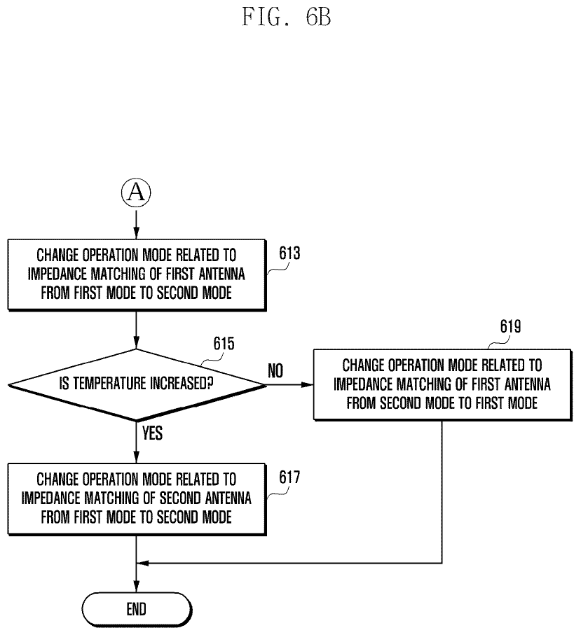

FIGS. 6A and 6B are diagrams illustrating an example of performing, by an electronic device, impedance matching of a first antenna and/or a second antenna based on the number of uplink layers allocated to the electronic device according to various embodiments of the disclosure.

The electronic device (e.g., electronic device 101 of FIG. 5) may identify that the number of layers allocated to the electronic device 101 satisfies a specified condition in operation 601 of flowchart 600.

The electronic device 101 may identify the number of uplink layers allocated by the cellular network 394 to the electronic device 101, while operating in a mode (UL-MIMO) that transmits data to the cellular network 394 via the first antenna 551 and the second antenna 553.

According to an embodiment, when a size of data transmitted to the cellular network 394 satisfies a specified condition, the electronic device 101 may identify the number of uplink layers allocated to the electronic device 101. For example, the specified condition may be a condition related to a situation expected to have high heat generation and/or high power consumption. According to an embodiment, the specified condition may include a condition that a size (or throughput) of data transmitted or received during a specified time is greater than or equal to (or exceeds) a specified size (e.g., 17.5 Mbps). For example, the number of uplink layers may be the average of the number of uplink layers allocated during the specified time.

According to an embodiment, the electronic device 101 may identify the number of uplink layers allocated to the electronic device 101 upon detecting that a predetermined component of the electronic device 101 is activated. For example, the predetermined component may be a component that causes high heat generation and/or high power consumption. According to another embodiment, the predetermined component may include a display, a front camera, or a rear camera of the electronic device 101.

The electronic device 101 may identify the number of uplink layers allocated to the electronic device 101 based on control information received from the cellular network 394 via the base station 450.

The electronic device 101 may receive downlink control information (DCI) 1_0 from the cellular network 394. The electronic device 101 may identify the number of uplink layers allocated to the electronic device 101 by identifying a field (e.g., precoding information and number of layers) included in the DCI 1_0.

According to an embodiment, the electronic device 101 may receive the DCI 1_0 from the cellular network 394. The electronic device 101 may identify (or estimate) the number of uplink layers based on the number of SRSs included in a sounding reference signal (SRS) resource indicator among the fields included in the DCI 1_0.

In an embodiment, during operation in UL-MIMO, the electronic device 101 may continuously identify the number of uplink layers allocated to the electronic device 101, and may identify whether the number of uplink layers satisfies a specified condition. Alternatively, for example, the electronic device 101 may identify whether the average of the number of uplink layers allocated to the electronic device 101 satisfies a specified condition. According to an embodiment, the specified condition may be a condition in which the electronic device 101 has difficulty in achieving high throughput while operating in UL-MIMO. For example, to achieve high throughput while the electronic device 101 operates in UL-MIMO, the electronic device 101 may need to be assigned with a higher number of uplink layers from the cellular network 394. Therefore, the specified condition may be a condition that the number of uplink layers allocated to the electronic device 101 is less than or equal to (or less than) a specified value. According to another embodiment, the specified condition may include a condition that the number of uplink layers or the average of the number of uplink layers is less than or equal to (or less than) a specified value (e.g., 1.5).

According to an embodiment, when the number of uplink layers does not satisfy the specified condition, the electronic device 101 may configure (or maintain) an operation mode related to impedance matching of at least one of the first antenna 551 and the second antenna 553 as a first mode that improves the performance of impedance matching.

In another embodiment, the electronic device 101 may identify whether performance of the first antenna (e.g., first antenna 551 of FIG. 5) is lower than performance of the second antenna (e.g., second antenna 553 of FIG. 5) in operation 603.

When the number of uplink layers satisfies the specified condition, the electronic device 101 may change the operation mode related to impedance matching of at least one of the first antenna 551 and the second antenna 553 from the first mode that improves the performance of impedance matching to a second mode that reduces power consumption of an amplifier electrically connected to the at least one antenna. For example, the first mode may be a mode that performs impedance matching when a voltage with a higher magnitude is applied to the amplifier, the magnitude of the voltage being higher than a magnitude of a voltage (or current) applied to the amplifier electrically connected to the antenna when the matching circuit operates in the second mode. For example, the second mode may be a mode that performs impedance matching when a voltage with a lower magnitude is applied to the amplifier, the magnitude of the voltage being lower than a magnitude of a voltage (or current) applied to the amplifier electrically connected to the antenna when the matching circuit operates in the first mode.

According to an embodiment, the electronic device 101, in the configured operation mode, may decrease a voltage (or bias voltage) applied to an amplifier included in a front end module (e.g., first front end module 533) electrically connected to at least one antenna (e.g., first antenna 551), and the electronic device 101 may input an antenna code corresponding to the configured operation mode to a matching circuit electrically connected to the at least one antenna, thereby performing impedance matching of the at least one antenna. The antenna code may refer to control data for controlling the various components included in the matching circuit. By performing impedance matching of the antenna in the second mode that may reduce power consumption, the electronic device 101 may reduce power consumption and heat generation caused by operation of UL-MIMO, and may prevent UL-MIMO disablement caused due to an increase in the temperature of the electronic device 101. Accordingly, the electronic device 101 may perform UL-MIMO for a relatively long time.

When performance of the first antenna 551 is lower than performance of the second antenna 553 (Y in operation 603), the electronic device 101 may change an operation mode related to impedance matching of the second antenna 553 from the first mode to the second mode in operation 605.

According to an embodiment, the electronic device 101 may select an antenna (e.g., second antenna 553) that shows higher performance between the first antenna 551 and the second antenna 553, as an antenna for which an operation mode related to impedance matching is to be changed. When an operation mode related to impedance matching of an antenna that has relatively higher performance is configured to an operation mode that may consume a relatively low amount of power, deterioration in a data transmission speed may be decreased and power consumption may be reduced.

According to an embodiment, the electronic device 101 may use the quality of signals (e.g., reference signals received power (RSRP)) that may be received via the first antenna 551 and the second antenna 553, when determining the performance of the first antenna 551 and the second antenna 553. According to another embodiment, the electronic device 101 may compare an RSRP of a signal received via the first antenna 551 and an RSRP received via the second antenna 553, and may select an antenna (e.g., second antenna 553) corresponding to a higher RSRP. The electronic device 101 may perform impedance matching of the second antenna 553 by inputting the antenna code corresponding to the configured operation mode to the second matching circuit 543.

According to an embodiment, the electronic device 101 may use maximum output strengths (maximum transmit power (MTP)) of the first antenna 551 and the second antenna 553, when determining the performance of the first antenna 551 and the second antenna 553. According to an embodiment, the electronic device 101 may compare a strength (MTP) of a signal capable of being output via the first antenna 551 and a strength (MTP) of a signal capable of being output via the second antenna 553, and may select an antenna (e.g., second antenna 553) capable of performing output with a higher strength. The electronic device 101 may perform impedance matching of the second antenna 553 by inputting the antenna code corresponding to the configured operation mode to the second matching circuit 543.

According to an embodiment, the electronic device 101 may identify whether a temperature of a portion of the electronic device 101 is increased after performing operation 605, in operation 607.

For example, the electronic device 101 may identify (or monitor) a temperature of a portion of the electronic device 101 after performing impedance matching of the second antenna 553 in the second mode.

When the temperature of the portion of the electronic device 101 is increased (Y in operation 607), the electronic device 101 may change an operation mode related to impedance matching of the first antenna 551 from the first mode to the second mode, in operation 609.

For example, when the temperature of the portion of the electronic device 101 is increased by a specified magnitude or greater (or greater than the specified magnitude), the electronic device 101 may change (or configure), to the second mode, an operation mode related to impedance matching of another antenna (e.g., first antenna 551) corresponding to a matching circuit operating in the first mode.

The electronic device 101, in the configured operation mode, may decrease a voltage (or bias voltage) applied to an amplifier included in a front end module (e.g., first front end module 533) electrically connected to the other antenna (e.g., first antenna 551), and the electronic device 101 may input an antenna code corresponding to the configured operation mode to a matching circuit (e.g., first matching circuit 541) electrically connected to the other antenna (e.g., first antenna 551), thereby performing impedance matching of the other antenna. The antenna code may refer to control data for controlling the various components included in the matching circuit. By performing impedance matching of the other antenna using the first matching circuit 541 operating in the second mode that may reduce power consumption, the electronic device 101 may reduce power consumption and heat generation caused by operation of UL-MIMO, and may prevent UL-MIMO disablement caused due to an increase in the temperature of the electronic device 101. Accordingly, the electronic device 101 may perform UL-MIMO for a relatively long time.

In an embodiment, when the temperature of the portion of the electronic device 101 is not increased (N in operation 607), the electronic device 101 may change the operation mode related to impedance matching of the second antenna 553 from the second mode to the first mode, in operation 611.

According to an embodiment, when the temperature of the portion of the electronic device 101 is decreased by a specified magnitude or greater (or greater than the specified magnitude), the electronic device 101 may change the operation mode related to impedance matching of the second antenna 553 again from the second mode to the first mode.

In another embodiment, the electronic device 101, in the first mode, may increase a voltage (or bias voltage) applied to an amplifier included in a front end module (e.g., first front end module 533) electrically connected to at least one antenna (e.g., first antenna 551), and the electronic device 101 may input an antenna code corresponding to the first mode to a matching circuit electrically connected to the at least one antenna, thereby performing impedance matching of the at least one antenna. The antenna code may refer to control data for controlling various components included in the matching circuit. The electronic device 101 may perform impedance matching of the at least one antenna by inputting the antenna code corresponding to the configured operation mode to the matching circuit corresponding to the at least one antenna. When the temperature is decreased again, the electronic device 101 may change to the first mode that may achieve higher throughput than the second mode, so as to improve a data transmission speed.

According to an embodiment, when performance of the first antenna 551 is higher than performance of the second antenna 553 (N in operation 603), the electronic device 101 may change the operation mode related to impedance matching of the first antenna 551 from the first mode to the second mode in operation 613.

The electronic device 101 may select an antenna (e.g., first antenna 551) that shows higher performance between the first antenna 551 and the second antenna 553, as an antenna for which an operation mode related to impedance matching is to be changed. When an operation mode related to impedance matching of the antenna having relatively higher performance is configured to an operation mode that may consume a relatively low amount of power, deterioration in a data transmission speed may be decreased and power consumption may be reduced.

According to an embodiment, the electronic device 101 may use the quality of signals (e.g., reference signals received power (RSRP)) that may be received via the first antenna 551 and the second antenna 553, when determining the performance of the first antenna 551 and the second antenna 553. According to an embodiment, the electronic device 101 may compare an RSRP of a signal received via the first antenna 551 and an RSRP received via the second antenna 553, and may select an antenna (e.g., first antenna 551) corresponding to a higher RSRP. The electronic device 101 may perform impedance matching of the first antenna 551 by inputting an antenna code corresponding to the configured operation mode to the first matching circuit 541.

The electronic device 101 may use maximum output strengths (maximum transmit power (MTP)) of the first antenna 551 and the second antenna 553, when determining the performance of the first antenna 551 and the second antenna 553. According to an embodiment, the electronic device 101 may compare a strength (MTP) of a signal capable of being output via the first antenna 551 and a strength (MTP) of a signal capable of being output via the second antenna 553, and may select an antenna (e.g., first antenna 551) capable of performing output with a higher strength. The electronic device 101 may perform impedance matching of the first antenna 551 by inputting the antenna code corresponding to the configured operation mode to the first matching circuit 541.

According to an embodiment, the electronic device 101, in the second mode, may decrease a voltage (or bias voltage) applied to an amplifier included in a front end module (e.g., first front end module 533) electrically connected to at least one antenna (e.g., first antenna 551), and the electronic device 101 may input an antenna code corresponding to the second mode to the first matching circuit 541 electrically connected to the first antenna 551, thereby performing impedance matching of the first one antenna 551. The antenna code may refer to control data for controlling various components included in the matching circuit. The electronic device 101 may perform impedance matching of the first antenna 551 by inputting an antenna code corresponding to the configured operation mode to the matching circuit corresponding to the at least one antenna.

According to another embodiment, the electronic device 101 may identify whether a temperature of a portion of the electronic device 101 is increased after performing operation 613, in operation 615.

According to an embodiment, when the temperature of the portion of the electronic device 101 is increased (Y in operation 615), the electronic device 101 may change the operation mode related to impedance matching of the second antenna 553 from the first mode to the second mode, in operation 617.

For example, when the temperature of the portion of the electronic device 101 is increased by a specified magnitude or greater (or greater than the specified magnitude), the electronic device 101 may change (or configure), to the second mode, an operation mode related to impedance matching of another antenna (e.g., second antenna 553) corresponding to a matching circuit operating in the first mode.

The electronic device 101, in the configured operation mode, may decrease a voltage (or bias voltage) applied to an amplifier included in a front end module (e.g., second front end module 535) electrically connected to the other antenna (e.g., second antenna 553), and the electronic device 101 may input an antenna code corresponding to the configured operation mode to a matching circuit (e.g., second matching circuit 543) electrically connected to the other antenna (e.g., second antenna 553), thereby performing impedance matching of the other antenna. The antenna code may refer to control data for controlling various components included in the matching circuit. By performing impedance matching of the other antenna in the second mode that may reduce power consumption, the electronic device 101 may decrease power consumption and heat generation caused by operation of UL-MIMO, and may prevent UL-MIMO disablement caused due to an increase in the temperature of the electronic device 101. Accordingly, the electronic device 101 may perform UL-MIMO for a relatively long time.

According to yet another embodiment, when the temperature of the portion of the electronic device 101 is not increased (N in operation 615), the electronic device 101 may change the operation mode related to impedance matching of the first antenna 551 from the second mode to the first mode, in operation 619.

According to an embodiment, the electronic device 101, in the first mode, may increase a voltage (or bias voltage) applied to an amplifier included in a front end module (e.g., first front end module 533) electrically connected to at least one antenna (e.g., first antenna 551), and the electronic device 101 may input an antenna code corresponding to the first mode to the first matching circuit 541 electrically connected to the first antenna 551, thereby performing impedance matching of the first one antenna 551. The antenna code may refer to control data for controlling various components included in the matching circuit. The electronic device 101 may, for example, perform impedance matching of the first antenna 551 by inputting the antenna code corresponding to the configured operation mode to the first matching circuit 541 corresponding to the first antenna 551. When the temperature is decreased again, the electronic device 101 may change to the first mode that may achieve higher throughput than the second mode, so as to improve a data transmission speed.

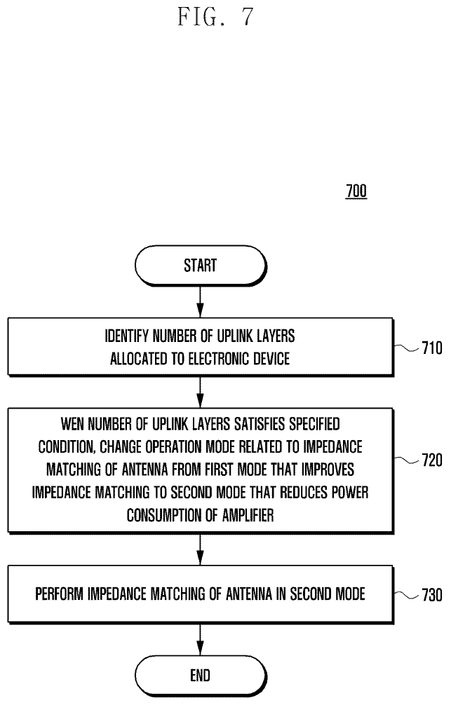

FIG. 7 is a flowchart illustrating an operation method 700 of an electronic device according to an embodiment of the disclosure.

An electronic device (e.g., electronic device 101 of FIG. 5) may identify the number of uplink layers allocated to the electronic device 101 in operation 710.

According to an embodiment, the electronic device 101 may identify the number of uplink layers that the cellular network 394 allocates to the electronic device 101, while operating in a mode (UL-MIMO) that transmits data to the cellular network 394 via the first antenna 551 and the second antenna 553.

According to an embodiment, when a size of data transmitted to the cellular network 394 satisfies a specified condition, the electronic device 101 may identify the number of uplink layers allocated to the electronic device 101. For example, the specified condition may be a condition related to a situation expected to have high heat generation and/or high power consumption. According to another embodiment, the specified condition may include a condition that a size (or throughput) of data transmitted or received during a specified time is greater than or equal to (or exceeds) a specified size (e.g., 17.5 Mbps).

The electronic device 101 may identify the number of uplink layers allocated to the electronic device 101 upon detecting that a predetermined component of the electronic device 101 is activated. For example, the predetermined component may be a component that causes high heat generation and/or high power consumption. According to an embodiment, the predetermined component may include a display, a front camera, or a rear camera of the electronic device 101.

The electronic device 101 may identify the number of uplink layers allocated to the electronic device 101 based on control information received from the cellular network 394 via the base station 450.

According to another embodiment, the electronic device 101 may receive downlink control information (DCI) 1_0 from the cellular network 394. The electronic device 101 may identify the number of uplink layers allocated to the electronic device 101 by identifying a field (e.g., precoding information and number of layers) included in the DCI 1_0.

The electronic device 101 may receive the DCI 1_0 from the cellular network 394. The electronic device 101 may identify (or estimate) the number of uplink layers based on the number of SRSs included in a sounding reference signal (SRS) resource indicator among the fields included in the DCI 1_0.

When the number of uplink layers satisfies a specified condition, the electronic device 101 may change an operation mode related to impedance matching of an antenna from a first mode that improves impedance matching to a second mode that reduces power consumption of an amplifier, in operation 720.

While operating in UL-MIMO, the electronic device 101 may continuously identify the number of uplink layers allocated to the electronic device 101, and may identify whether the number of uplink layers satisfies the specified condition. Alternatively, the electronic device 101 may identify whether the average of the number of uplink layers allocated to the electronic device 101 satisfies the specified condition. According to an embodiment, the specified condition may be a condition that has difficulty in achieving high throughput while the electronic device 101 operates in UL-MIMO. In an example, to achieve high throughput while the electronic device 101 operates in UL-MIMO, the electronic device 101 may need to be assigned with a higher number of uplink layers from the cellular network 394. Therefore, the specified condition may be a condition that the number of uplink layers allocated to the electronic device 101 is less than or equal to (or less than) a specified value. According to an embodiment, the specified condition may include a condition that the number of uplink layers or the average of the number of uplink layers is less than or equal to (or less than) a specified value (e.g., 1.5).

According to an embodiment, when the number of uplink layers does not satisfy the specified condition, the electronic device 101 may configure (or maintain) an operation mode related to impedance matching of at least one of the first antenna 551 and the second antenna 553 as the first mode that improves the performance of the antenna.

According to another embodiment, when the number of uplink layers satisfies the specified condition, the electronic device 101 may change an operation mode related to impedance matching of at least one of the first antenna 551 and the second antenna 553 from the first mode that improves the performance of impedance matching to the second mode that reduces power consumption of an amplifier electrically connected to the at least one antenna. The first mode may be a mode that performs impedance matching when a voltage with a higher magnitude is applied to an amplifier, the magnitude of the voltage being higher than a magnitude of a voltage (or current) applied to the amplifier electrically connected to the antenna when the matching circuit operates in the second mode. The second mode may be a mode that performs impedance matching when a voltage with a lower magnitude is applied to an amplifier, the magnitude of the voltage being lower than a magnitude of a voltage (or current) applied to the amplifier electrically connected to the antenna when the matching circuit operates in the first mode.

In an embodiment, the electronic device 101, in the configured operation mode, may decrease a voltage (or bias voltage) applied to an amplifier included in a front end module (e.g., first front end module 533) electrically connected to at least one antenna (e.g., first antenna 551), and the electronic device 101 may input an antenna code corresponding to the configured operation mode to a matching circuit electrically connected to the at least one antenna, thereby performing impedance matching of the at least one antenna. The antenna code may refer to control data for controlling various components included in the matching circuit. By performing impedance matching of an antenna in the second mode that may reduce power consumption, the electronic device 101 may reduce power consumption and heat generation caused by operation of UL-MIMO, and may prevent UL-MIMO disablement caused due to an increase in the temperature of the electronic device 101. Accordingly, the electronic device 101 may perform UL-MIMO for a relatively long time.

According to an embodiment, the electronic device 101 may select an antenna (e.g., first antenna 551) that shows higher performance between the first antenna 551 and the second antenna 553, as an antenna for which an operation mode related to impedance matching is to be changed. When an operation mode related to impedance matching of the antenna having relatively higher performance is configured to an operation mode that may consume a relatively low amount of power, deterioration in a data transmission speed may be decreased and power consumption may be reduced.

The electronic device 101 may use the quality of signals (e.g., reference signals received power (RSRP)) that may be received via the first antenna 551 and the second antenna 553, when determining the performance of the first antenna 551 and the second antenna 553. According to an embodiment, the electronic device 101 may compare an RSRP of a signal received via the first antenna 551 and an RSRP received via the second antenna 553, and may select an antenna (e.g., first antenna 551) corresponding to a higher RSRP. The electronic device 101 may perform impedance matching of the first antenna 551 by inputting an antenna code corresponding to the configured operation mode to the first matching circuit 541.

According to another embodiment, the electronic device 101 may use maximum output strengths (maximum transmit power (MTP)) of the first antenna 551 and the second antenna 553, when determining the performance of the first antenna 551 and the second antenna 553. The electronic device 101 may compare a strength (MTP) of a signal capable of being output via the first antenna 551 and a strength (MTP) of a signal capable of being output via the second antenna 553, and may select an antenna (e.g., first antenna 551) capable of performing output with a higher strength. The electronic device 101 may perform impedance matching of the first antenna 551 by inputting an antenna code corresponding to the configured operation mode to the first matching circuit 541.

According to an embodiment, the electronic device 101 may perform impedance matching of the antenna in the second mode in operation 730.

According to an embodiment, the electronic device 101, in the second mode, may decrease a voltage (or bias voltage) applied to an amplifier included in a front end module (e.g., first front end module 533) electrically connected to at least one antenna (e.g., first antenna 551), and the electronic device 101 may input an antenna code corresponding to the second mode to a matching circuit electrically connected to the at least one antenna, thereby performing impedance matching of the at least one antenna. The antenna code may refer to control data for controlling various components included in the matching circuit. The electronic device 101 may perform impedance matching of the at least one antenna by inputting the antenna code corresponding to the configured operation mode to the matching circuit corresponding to the at least one antenna.

An electronic device (e.g., electronic device 101 of FIG. 5) according to an embodiment may include a first antenna (e.g., first antenna 551 of FIG. 5). The electronic device 101 may include a second antenna (e.g., second antenna 553 of FIG. 5). The electronic device 101 may include a communication processor (e.g., communication processor 510 of FIG. 5). During operation in a mode in which data is transmitted to a cellular network (e.g., 5G network 394 of FIG. 3) via the first antenna 551 and the second antenna 553, the communication processor 510 may identify the number of uplink layers that the cellular network 394 allocates to the electronic device 101. When the number of uplink layers allocated to the electronic device 101 during a specified time satisfies a specified condition, the communication processor 510 may, for example, change an operation mode related to impedance matching of at least one (e.g., first antenna 551) of the first antenna 551 and the second antenna 553 from a first mode that improves performance of impedance matching of the at least one antenna (e.g., first antenna 551) to a second mode that reduces power consumption of an amplifier electrically connected to the at least one antenna (e.g., first antenna 551). The communication processor 510 may be configured to perform impedance matching of the at least one antenna (e.g., first antenna 551) in the second mode.

In the electronic device 101 according to an embodiment, the communication processor 510 may select an antenna that shows higher performance between the first antenna 551 and the second antenna 553. The communication processor 510 may be configured to perform impedance matching of the selected antenna in the second mode.

In the electronic device 101, the specified condition may include a condition that the number of uplink layers allocated to the electronic device 101 is less than or equal to a specified value.

In the electronic device 101 according to an embodiment, when the number of the uplink layers does not satisfy the specified condition, the communication processor 510 may be configured to maintain the operation mode related to impedance matching of the first antenna 551 and the second antenna as the first mode.

In the electronic device 101, when a temperature of at least a portion of the electronic device 101 is increased after performing impedance matching of the at least one antenna (e.g., first antenna 551) in the second mode, the communication processor 510 may change an operation mode related to impedance matching of another antenna (e.g., second antenna 553) from the first mode to the second mode.

The communication processor 510 may be configured to perform impedance matching of the other antenna (e.g., second antenna 553) in the second mode.

In the electronic device 101 according to an embodiment, when a temperature of at least a portion of the electronic device 101 is increased after performing impedance matching of the first antenna 551 and the second antenna 553 in the second mode, the communication processor 510 may be configured to terminate a connection to the cellular network 394 via first cellular communication and establish a connection to the cellular network 394 via second cellular communication.

In the electronic device 101, the communication processor 510 may be configured to maintain a mode that transmits data to the first cellular network 394 via the first antenna 551 and the second antenna 553 after performing impedance matching of the at least one antenna (e.g., first antenna 551) in the second mode.

In the electronic device 101 according to an embodiment, when a temperature of at least a portion of the electronic device 101 is decreased after performing impedance matching of the at least one in the second mode, the communication processor 510 may change the operation mode related to impedance matching of the at least one antenna (e.g., first antenna 551) from the second mode to the first mode. The communication processor 510 may be configured to perform impedance matching of the at least one antenna (e.g., first antenna 551) in the first mode.

In the electronic device 101, the communication processor 510 may decrease a bias voltage applied to an amplifier electrically connected to the at least one antenna (e.g., first antenna 551) in the second mode. The communication processor 510 may be configured to perform impedance matching of the at least one antenna (e.g., first antenna 551) after the bias voltage is decreased.

In the electronic device 101 according to an embodiment, when a size of data transmitted to the cellular network 394 is greater than or equal to a specified size, the communication processor 510 may be configured to identify whether the number of uplink layers allocated to the electronic device 101 during the specified time satisfies the specified condition.

The operation method of the electronic device 101 may include an operation of identifying the number of uplink layers allocated by the cellular network 394 to the electronic device 101 during operation in a mode in which data is transmitted to the cellular network 394 via the first antenna 551 and the second antenna 553. The operation method of the electronic device 101 may, for example, include an operation of changing an operation mode related to impedance matching of at least one (e.g., first antenna 551) of the first antenna 551 and the second antenna 553 from a first mode that improves performance of impedance matching of the at least one antenna (first antenna 551) to a second mode that reduces power consumption of an amplifier electrically connected to the at least one antenna (e.g., first antenna 551) when the number of uplink layers allocated to the electronic device 101 during a specified time satisfies a specified condition. The operation method of the electronic device 101 may include an operation of performing impedance matching of the at least one antenna (e.g., first antenna 551) in the second mode.

The operation method of the electronic device 101 according to an embodiment may further include an operation of selecting an antenna that shows higher performance between the first antenna 551 and the second antenna 553. The operation method of the electronic device 101 may further include an operation of performing impedance matching of the selected antenna in the second mode.

In the operation method of the electronic device 101, the specified condition may include a condition that the number of uplink layers allocated to the electronic device 101 is less than or equal to a specified value.

The operation method of the electronic device 101 according to an embodiment may further include an operation of maintaining the operation mode related to impedance matching of the first antenna 551 and the second antenna as the first mode when the number of uplink layers does not satisfy the specified condition.

The operation method of the electronic device 101 may further include an operation of changing an operation mode related to impedance matching of another antenna (e.g., second antenna 553) from the first mode to the second mode when a temperature of at least a portion of the electronic device 101 is increased after performing impedance matching of the at least one antenna (e.g., first antenna 551) in the second mode. The operation method of the electronic device 101 may further include an operation of performing impedance matching of the other antenna (e.g., second antenna 553) in the second mode.

The operation method of the electronic device 101 may further include an operation of terminating a connection to the cellular network 394 via first cellular communication and establishing a connection to the cellular network 394 via second cellular communication when a temperature of at least a portion of the electronic device 101 is increased after performing impedance matching of the first antenna 551 and the second antenna 553 in the second mode.

The operation method of the electronic device 101 according to an embodiment may further include an operation of maintaining the mode that transmits data to the first cellular network 394 via the first antenna 551 and the second antenna 553 after performing impedance matching of the at least one antenna (e.g., first antenna 551) in the second mode.

The operation method of the electronic device 101 may further include an operation of changing the operation mode related to impedance matching of the at least one antenna (e.g., first antenna 551) from the second mode to the first mode when a temperature of at least a portion of the electronic device 101 is decreased after performing impedance matching of the at least one in the second mode. The operation method of the electronic device 101 may include an operation of performing impedance matching of the at least one antenna (e.g., first antenna 551) in the first mode.

The operation method of the electronic device 101 according to an embodiment may further include an operation of decreasing a bias voltage applied to an amplifier electrically connected to the at least one antenna (e.g., first antenna 551) in the second mode. The operation method of the electronic device 101 may further include an operation of performing impedance matching of the at least one antenna (e.g., first antenna 551) after the bias voltage is decreased.

The operation method of the electronic device 101 according to an embodiment may further include an operation of identifying whether the number of uplink layers allocated to the electronic device 101 during the specified time satisfies the specified condition when a size of data transmitted to the cellular network 394 is greater than or equal to a specified size.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used herein, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

A method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities. According to other embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

It will be appreciated that various embodiments of the disclosure according to the claims and description in the specification can be realized in the form of hardware, software or a combination of hardware and software.

Any such software may be stored in non-transitory computer readable storage media. The non-transitory computer readable storage media store one or more computer programs (software modules), the one or more computer programs include computer-executable instructions that, when executed by one or more processors of an electronic device individually or collectively, cause the electronic device to perform a method of the disclosure.

Any such software may be stored in the form of volatile or non-volatile storage such as, for example, a storage device like read only memory (ROM), whether erasable or rewritable or not, or in the form of memory such as, for example, random access memory (RAM), memory chips, device or integrated circuits or on an optically or magnetically readable medium such as, for example, a compact disk (CD), digital versatile disc (DVD), magnetic disk or magnetic tape or the like. It will be appreciated that the storage devices and storage media are various embodiments of non-transitory machine-readable storage that are suitable for storing a computer program or computer programs comprising instructions that, when executed, implement various embodiments of the disclosure. Accordingly, various embodiments provide a program comprising code for implementing apparatus or a method as claimed in any one of the claims of this specification and a non-transitory machine-readable storage storing such a program.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. An electronic device, comprising:
a first antenna;
a second antenna;
memory, comprising one or more storage media, storing instructions; and
at least one communication processor communicatively coupled to the first antenna, the second antenna, and the memory,
wherein the instructions, when executed by the at least one communication processor individually or collectively, cause the electronic device to:
during an operation in a mode in which data is transmitted to a cellular network via the first antenna and the second antenna, identify a number of uplink layers allocated by the cellular network to the electronic device,
in case that the number of uplink layers allocated to the electronic device during a specified time satisfies a specified condition, change an operation mode related to impedance matching of at least one of the first antenna and the second antenna from a first mode for improving performance of at least one antenna to a second mode for reducing power consumption of an amplifier electrically connected to the at least one antenna, and
perform impedance matching of the at least one antenna in the second mode.

2. The electronic device of claim 1, wherein the instructions, when executed by the at least one communication processor individually or collectively, further cause the electronic device to:
select an antenna that exhibits higher performance among the first antenna and the second antenna; and
perform impedance matching of the selected antenna in the second mode.

3. The electronic device of claim 1, wherein the specified condition comprises a condition that the number of uplink layers allocated to the electronic device is less than or equal to a specified value.

4. The electronic device of claim 1, wherein the instructions, when executed by the at least one communication processor individually or collectively, further cause the electronic device to:
in case that the number of the uplink layers does not satisfy the specified condition, maintain the operation mode related to impedance matching of the first antenna and the second antenna as the first mode.

5. The electronic device of claim 1, wherein the instructions, when executed by the at least one communication processor individually or collectively, further cause the electronic device to:
in case that a temperature of at least a portion of the electronic device is increased after performing impedance matching of the at least one antenna in the second mode, change an operation mode related to impedance matching of the other antenna from the first mode to the second mode; and
perform impedance matching of the other antenna in the second mode.

6. The electronic device of claim 5, wherein the instructions, when executed by the at least one communication processor individually or collectively, further cause the electronic device to, in case that a temperature of at least a portion of the electronic device is increased after performing impedance matching of the first antenna and the second antenna in the second mode, release a connection to the cellular network via first cellular communication and establish a connection to the cellular network via second cellular communication.

7. The electronic device of claim 1, wherein the instructions, when executed by the at least one communication processor individually or collectively, further cause the electronic device to:
after performing impedance matching of the at least one antenna in the second mode, maintain a mode in which data is transmitted to a first cellular network via the first antenna and the second antenna.

8. The electronic device of claim 1, wherein the instructions, when executed by the at least one communication processor individually or collectively, further cause the electronic device to:
in case that a temperature of at least a portion of the electronic device is decreased after performing impedance matching of the at least one in the second mode, change the operation mode related to impedance matching of the at least one antenna from the second mode to the first mode; and
perform impedance matching of the at least one antenna in the first mode.

9. The electronic device of claim 1, wherein the instructions, when executed by the at least one communication processor individually or collectively, further cause the electronic device to:
decrease a bias voltage applied to the amplifier electrically connected to the at least one antenna in the second mode; and
perform impedance matching of the at least one antenna after the bias voltage is decreased.

10. The electronic device of claim 1, wherein the instructions, when executed by the at least one communication processor individually or collectively, further cause the electronic device to:
in case that a size of data transmitted to the cellular network is greater than or equal to a specified size, identify whether the number of uplink layers allocated to the electronic device during the specified time satisfies the specified condition.

11. A method of operating an electronic device, the method comprising:
during an operation in a mode in which data is transmitted to a cellular network via a first antenna and a second antenna, identifying a number of uplink layers allocated by the cellular network to the electronic device;
in case that the number of uplink layers allocated to the electronic device during a specified time satisfies a specified condition, changing an operation mode related to impedance matching of at least one of the first antenna and the second antenna from a first mode for improving performance of at least one antenna to a second mode for reducing power consumption of an amplifier electrically connected to the at least one antenna; and
performing impedance matching of the at least one antenna in the second mode.

12. The method of claim 11, further comprising:
selecting an antenna that exhibits higher performance among the first antenna and the second antenna; and
performing impedance matching of the selected antenna in the second mode.

13. The method of claim 11, wherein the specified condition comprises a condition that the number of uplink layers allocated to the electronic device is less than or equal to a specified value.

14. The method of claim 11, further comprising:
in case that the number of uplink layers does not satisfy the specified condition, maintaining the operation mode related to impedance matching of the first antenna and the second antenna as the first mode.

15. The method of claim 11, further comprising:
in case that a temperature of at least a portion of the electronic device is increased after performing impedance matching of the at least one antenna in the second mode, changing an operation mode related to impedance matching of the other antenna from the first mode to the second mode; and
performing impedance matching of the other antenna in the second mode.

16. The method of claim 11, further comprising:
in case that a temperature of at least a portion of the electronic device is increased after performing impedance matching of the first antenna and the second antenna in the second mode, releasing a connection to the cellular network via first cellular communication and establish a connection to the cellular network via second cellular communication.

17. The method of claim 11, further comprising:
after performing impedance matching of the at least one antenna in the second mode, maintaining a mode in which data is transmitted to a first cellular network via the first antenna and the second antenna.

18. The method of claim 11, further comprising:
in case that a temperature of at least a portion of the electronic device is decreased after performing impedance matching of the at least one in the second mode, changing the operation mode related to impedance matching of the at least one antenna from the second mode to the first mode; and
performing impedance matching of the at least one antenna in the first mode.

19. One or more non-transitory computer-readable storage media storing one or more computer programs including computer-executable instructions that, when executed by one or more processors of an electronic device individually or collectively, cause the electronic device to perform operations, the operations comprising:
during an operation in a mode in which data is transmitted to a cellular network via a first antenna and a second antenna, identifying a number of uplink layers allocated by the cellular network to the electronic device;
in case that the number of uplink layers allocated to the electronic device during a specified time satisfies a specified condition, changing an operation mode related to impedance matching of at least one of the first antenna and the second antenna from a first mode for improving performance of at least one antenna to a second mode for reducing power consumption of an amplifier electrically connected to the at least one antenna; and
performing impedance matching of the at least one antenna in the second mode.

20. The one or more non-transitory computer-readable storage media of claim 19, the operations further comprising:
selecting an antenna that exhibits higher performance among the first antenna and the second antenna; and
performing impedance matching of the selected antenna in the second mode.
